(19) United States
(12) Patent Application Publication
(10) Pub. No.: US 2013/0009250 A1
(43) Pub. Date: Jan. 10, 2013

(54) DUMMY PATTERNS FOR IMPROVING WIDTH DEPENDENT DEVICE MISMATCH IN HIGH-K METAL GATE PROCESS

(75) Inventors: Tung-Hsing LEE, Lujhou City (TW); Tse-Hsiang HSU, Hsin-Chu City (TW); Ching-Chung KO, Jhubei City (TW)

(73) Assignee: MEDIATEK INC., Hsin-Chu (TW)

(21) Appl. No.: 13/482,374

(22) Filed: May 29, 2012

Related U.S. Application Data
(60) Provisional application No. 61/504,764, filed on Jul. 6, 2011.

(51) Int. Cl. H01L 27/092

(52) U.S. Cl. 257/369; 257/E27.062

(57) ABSTRACT

A semiconductor integrated circuit device including: a diffusion area defined by an isolation region in a substrate; a PMOS transistor comprising a metal gate and a high-k dielectric over the diffusion area and source/drain regions sandwiching the metal gate in a first direction; a plurality of dummy diffusion areas surrounding and spaced apart from the diffusion area; and a plurality of first dummy patterns at the two sides of the PMOS transistor in a second direction perpendicular to the first direction and between the dummy diffusion areas and the diffusion area.

### CROSS REFERENCE TO RELATED APPILCATIONS

This application claims the benefit of U.S. Provisional Application No. 61/504,764 filed on Jul. 6, 2011, entitled “WIDTH DEPENDENCE MISMATCH IN HKMG PROCESS,” which application is hereby incorporated herein by reference.

### BACKGROUND OF THE INVENTION

1. Field of the Invention

The invention relates to a semiconductor integrated circuit device, and in particular relates to a semiconductor integrated circuit device which can improve the mismatch of a PMOS transistor having a large width.

2. Description of the Related Art

As technology nodes shrink, there has been a desire to replace the typical polysilicon gate electrode with a metal gate electrode to improve device performance of complementary metal-oxide semiconductor (CMOS) transistors. One process of forming a metal gate electrode stack is a gate last process in which the metal gate electrode is formed in the final stage of the process. In other words, the gate structure of CMOS transistors is formed with a dummy semiconductor layer first, and the dummy semiconductor layer will be replaced with a metal layer as the metal gate electrode. Additionally, in order to reduce current leakage, high-k gate dielectrics are also used to provide enough effective thickness.

Mismatch is the differential performance of two or more devices on a single integrated circuit (IC). It is widely recognized that mismatch is a key to precise analog IC design. In particular, precise analog CMOS circuit design requires confident transistor mismatch models during the design and simulation stages.

One of the most important CMOS matching performance indicators is Avt, which relates the threshold voltage (Vt) mismatch fluctuations to the inverse square-root of the effective device area. The effective device area can be the multiple of the device length and the device width. Typically, the Avt of a p-type metal-oxide semiconductor (PMOS) transistor may be a constant with corresponding to a square-root of a multiple of the device length and the device width of the PMOS transistor. Thus, the threshold voltage of the PMOS transistor can be reduced by increasing the device length or the device width of the PMOS transistor. However, the Avt of the PMOS transistor cannot be maintained a constant and is dependent with the width of the PMOS transistor for precise analog CMOS circuit designs for such gate last processes as described above. Such a width dependent effect results in a larger area being sacrificed for obtaining the desired threshold voltage, and therefore larger power consumption will occur. Also, further shrinkage of the critical feature sizes of the MOS transistors will be difficult.

Thus, a new semiconductor integrated circuit device for CMOS circuit designs shall be provided for addressing the above issues.

### BRIEF SUMMARY OF INVENTION

Accordingly, a semiconductor integrated circuit device is provided. The semiconductor integrated circuit device includes a diffusion area defined by an isolation region in a substrate; a PMOS transistor comprising a metal gate and a high-k dielectric over the diffusion area and source/drain regions sandwiching the metal gate in a first direction; a plurality of dummy diffusion areas surrounding and spaced apart from the diffusion area; and a plurality of first dummy patterns at the two sides of the PMOS transistor in a second direction perpendicular to the first direction and between the dummy diffusion areas and the diffusion area.

Furthermore, a semiconductor integrated circuit device is also provided. The semiconductor integrated circuit device includes an active region which has a diffusion area in a substrate and is defined by an isolation region; a plurality of PMOS transistors, directly over the diffusion area, having a channel length parallel with a first direction; a plurality of dummy diffusion areas on the isolation region and surrounding the diffusion area; and a plurality of dummy patterns over the isolation region and between the dummy diffusion areas and the diffusion area, wherein the plurality of dummy patterns is only formed at the two sides of the plurality of PMOS transistor in a second direction perpendicular to the first direction.

In addition, a semiconductor integrated circuit device is also provided. The semiconductor integrated circuit device includes a diffusion area defined by an isolation region in a substrate; a PMOS transistor comprising a metal gate and a high-k dielectric over the diffusion area and source/drain regions sandwiching the metal gate in a first direction, wherein has a device width greater than 0.9 μm along a second direction perpendicular to the first direction; a NMOS transistor over the diffusion area and adjacent with the PMOS transistor, wherein the NMOS and the PMOS transistors are formed by a gate last process; a plurality of diffusion areas surrounding and spaced apart from the active region; and a plurality of first dummy patterns at the two sides of the PMOS transistor in the second direction and between the dummy diffusion areas and the diffusion area.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a top plan view of a semiconductor integrated circuit device at an intermediate stage of a gate last process;

FIG. 2 shows the AVts of NMOS and PMOS transistors with different device lengths and device widths, respectively;

FIG. 3 shows a cross-section of a PMOS transistor along the section X-X shown in FIG. 1;

FIGS. 4A to 4E show cross section views, in a direction along the channel length of the CMOS transistors, of intermediate stages of a gate last process for fabricating CMOS transistors; and

FIGS. 5A to 5C show top plan views of embodiments of a semiconductor integrated circuit device having dummy patterns formed at the two ends of the PMOS transistor in a direction of the device width of the PMOS transistors.

### DETAILED DESCRIPTION OF INVENTION

The following description is of the best-contemplated mode of carrying out the invention. This description is made for the purpose of illustrating the general principles of the invention and should not be taken in a limiting sense. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. The scope of the invention is best determined by reference to the appended claims.

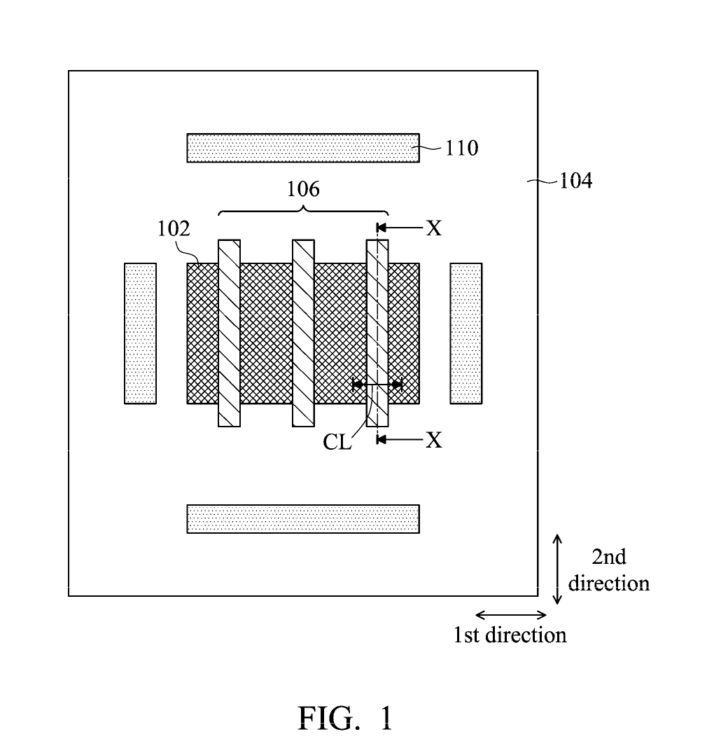

Referring to FIG. 1, illustrated is a top plan view of a semiconductor integrated circuit device at an intermediate stage of a gate last process in accordance with an embodiment of the present invention. The integrated circuit device may have an active region 102 surrounded and defined by an isolation region 104. In an embodiment, the active region 102 may comprise a diffusion area 102 where an array of complementary metal-oxide semiconductor (CMOS) transistors 106 is fabricated thereon according to the gate last process. Some dummy polygate structures may be formed over the dummy diffusion areas 110 corresponding to and surrounding the diffusion area 102 for preventing from over-polishing and/or dishing effect during performing a chemical metal polishing (CMP) process to metal gate layers and inter-layer dielectric layers.

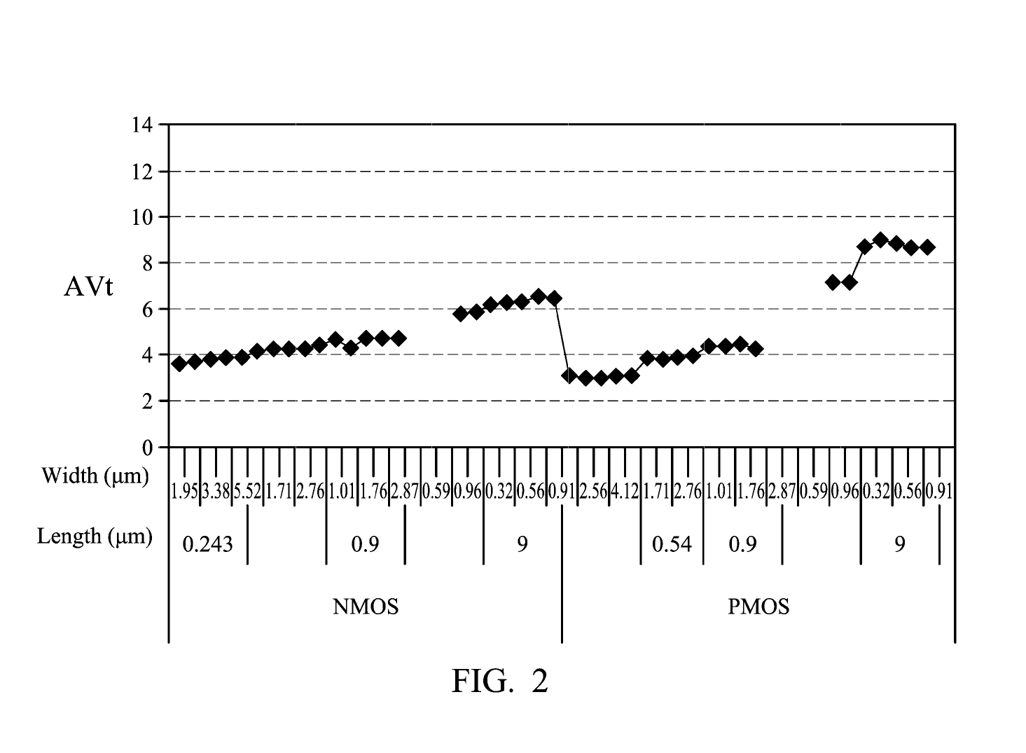

However, it is found that Avt of the p-type metal-oxide semiconductor (PMOS) transistor is dependent on a device width of the PMOS transistor for precise analog CMOS circuit design in the gate last process described above despite the dummy polygate structures being formed surrounding the active region. FIG. 2 shows the AVts of NMOS and PMOS transistors with different device lengths and device widths, respectively. As shown in FIG. 2, it shows that the PMOS transistor, unlike the NMOS transistor, may have AVts independent with the device length. However, the AVts of the PMOS transistor may get worse with an increased device width. In particular, the AVts may drastically get worse when the PMOS transistor has a device width greater than the device length, or when the PMOS transistor device has a device width greater than 0.9 μm. In the present disclosure, the device length of the PMOS and/or NMOS transistor is represented as the length of the PMOS and/or NMOS transistors along a direction perpendicular to its channel length, and the device width of the PMOS and/or NMOS transistor is represented as the length of the PMOS and/or NMOS transistors along a direction parallel with its channel length.

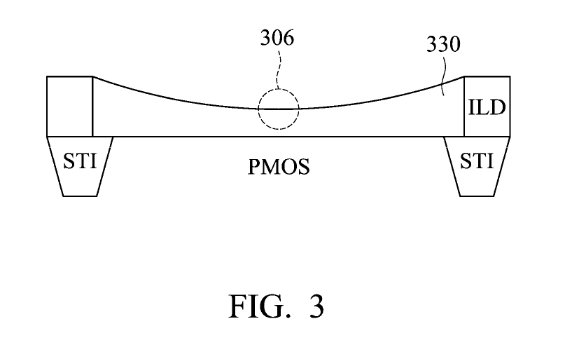

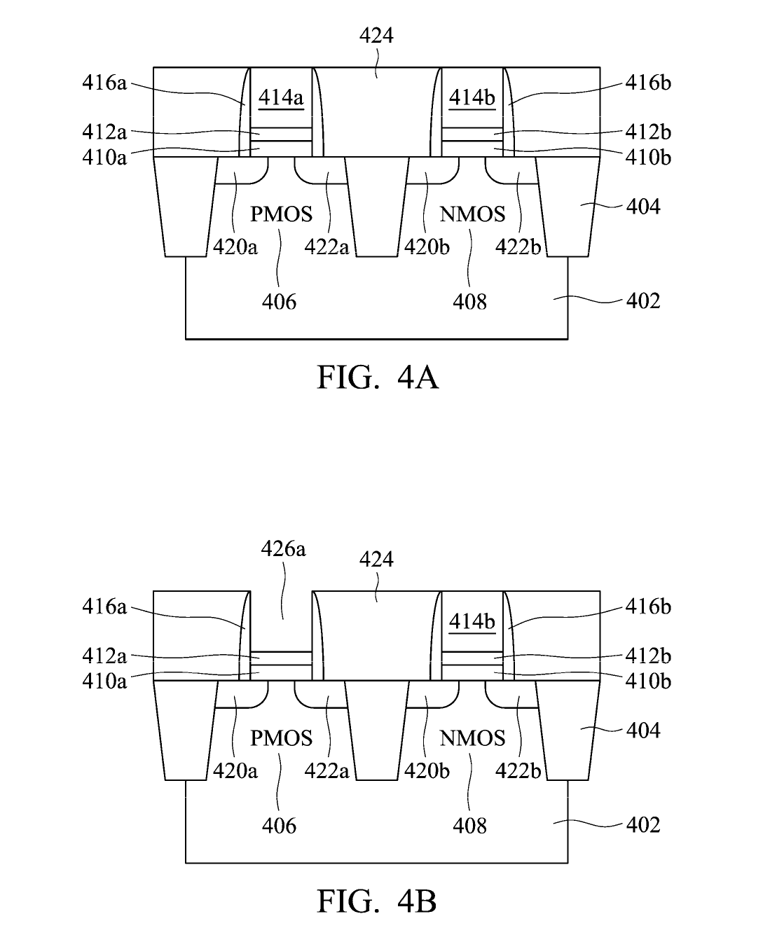

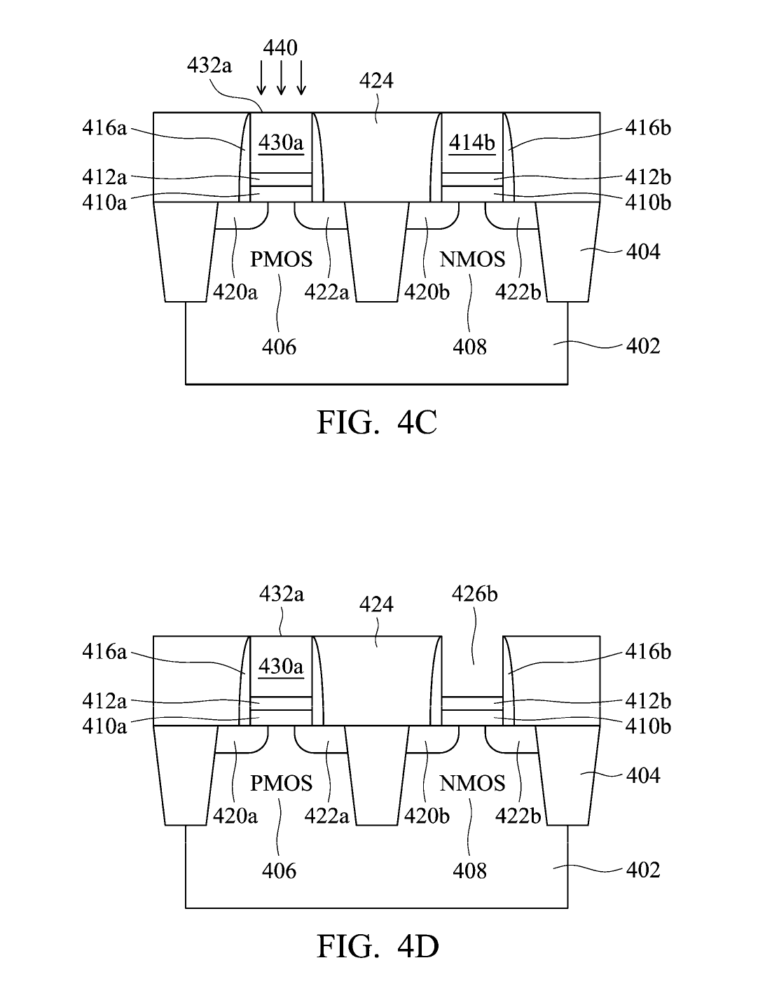

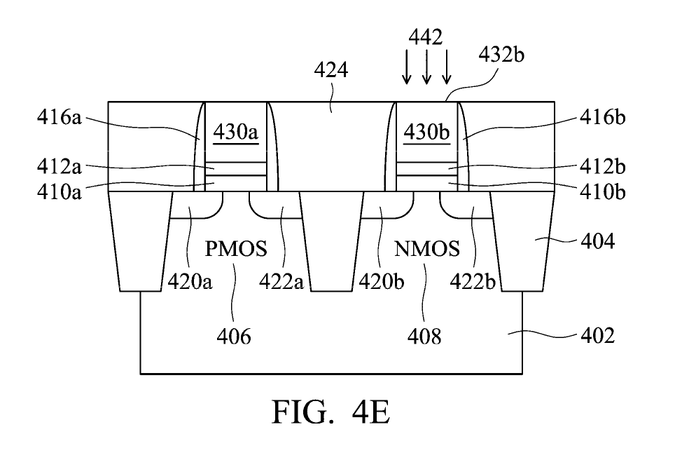

As shown in FIG. 3, illustrated is a cross-section of a PMOS transistor along the section X-X shown in FIG. 1. An erosion portion 306, which does not obviously present at the polysilicon gate electrode of the PMOS transistor, may be formed at the center of the metal gate electrode 330 of the PMOS transistor having a device width which is greater than its device length or greater than about 0.9 μm. During a gate last process, an extra CMP process, such as a second CMP process illustrated in FIG. 4E, may be performed to the NMOS transistor. However, the extra CMP process would also polish the metal gate electrode 330 of the PMOS transistor and result in over-polishing of the metal gate electrode 330. Thus, an erosion portion 306 at the center of the metal gate electrode 330 of the PMOS transistor is formed.

Referring to FIG. 4A to 4E, illustrated are cross section views, in a direction along the channel length of the CMOS transistors, of intermediate stages of a gate last process for fabricating CMOS transistors. Referring to FIG. 4A, an active region 402 comprising a PMOS region 406 and a NMOS region 408 is provided. The PMOS region 406 and the NMOS region 408 are separated from each other by shadow trench isolation (STI) regions 404. High-k dielectrics 410a and 410b are formed over the PMOS region 406 and the NMOS region 408, respectively. Diffusion barriers 412a and 412b are formed over the high-k dielectrics 410a and 410b. Dummy gates 414a and 414b are formed over the diffusion barriers 412a and 412b, respectively. Spacers 416a and 416b are formed on sidewalls of the dummy gates 414a and 414b, respectively. Doped regions, such as source/drain regions 420a, 420b, 422a and 422b, are within the substrate and sandwiches the dummy gates 414a and 414b. Thus, the active region 402 can be also referred to as the diffusion area 402 of CMOS transistors. An interlayer dielectric 424 (ILD) layer is around the spacers 416a and 416b. An isolation region (not shown) is adjacent and surrounds to the active region 402. Dummy diffusion areas (not shown) corresponding to the diffusion areas may be formed over and surround the isolation region.

The doped regions 420a and 420b may be p-type doped regions having dopants such as boron or other group III elements. The doped regions 422a and 422b may be n-type doped regions having dopants such arsenic, phosphorus, or other group V elements. The high-k dielectrics 410a and 410b may be formed of hafnium oxide, hafnium silicon oxide, hafnium tantalum oixide, hafnium silicon oxynitride, hafnium titanium oxide, hafnium zirconium oxide, other suitable high-k dielectric materials or combinations thereof.

The diffusion barriers 412a and 412b may prevent metallic ions of metal gate layers from diffusing into the above high-k dielectrics 418, respectively. The diffusion barriers 412a and 412b may comprise aluminum oxide, aluminum, aluminum nitride, titanium, titanium nitride, tantalum, tantalum or combinations thereof. The dummy gates 414a and 414b may include materials having an etching selectivity different from that of the ILD layer 424, for example, polysilicon or metal. The spacers 416a and 416b may include oxide, nitride, oxynitride, or combinations thereof. The ILD layer 424 may include low-k material, silicon oxide, silicon oxynitride, or other suitable dielectric materials.

Referring to FIG. 4B, the dummy gate 414a over the PMOS region 406 may be removed to form an opening 426a exposing the diffusion barrier layer 412a. A mask layer, such as a hard mask layer and/or a photoresist layer (not shown), can protect the dummy gate 414b from being removed. Referring to FIG. 4C, a metal gate electrode 430a for forming the PMOS transistor 432a is deposited within the opening 426a. The metal gate electrode 430a may include metal, metal carbide or metal nitride. The metal gate electrode 430a may have a p-type work function. The metal gate electrode 430a may be formed by physical vapor deposition (PVD), chemical vapor deposition (CVD), atom layer deposition (ALD), sputtering or other suitable deposition methods, and then be patterned by photolithography and etching processes. Furthermore, a first CMP process 440 is performed to the metal gate electrode 430a to remove the excess metal gate electrode over the opening 426a and provide the metal gate electrode 430a with a substantially smooth and flat surface.

Referring to FIG. 4D, the dummy gate 414b over the NMOS region 408 may be removed to form an opening 426b exposing the diffusion barrier layer 412b. Referring to FIG. 4E, a metal gate electrode 430b for forming the NMOS transistor 432b is deposited within the opening 426b. The metal gate electrode 426b may include metal, metal carbide or metal nitride. The metal gate electrode 426b may have an n-type work function. The metal gate layer 426b may be formed by PVD, CVD, ALD, sputtering or other suitable deposition methods, and then be patterned by photolithography and etching processes. Furthermore, a second CMP process 442 is performed to the metal gate electrode 430b to remove the excess metal gate electrode over the opening 426b and provide the metal gate electrode 430b with a substantially flat surface. Note that the metal gate electrode 430a may be also polished by the second CMP process 442 resulting in the erosion portion 306 shown in FIG. 3.

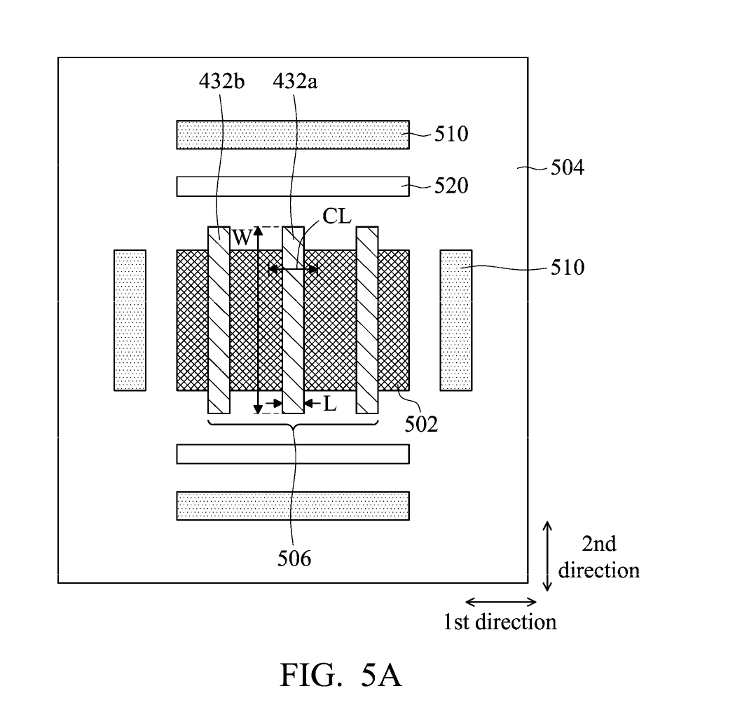

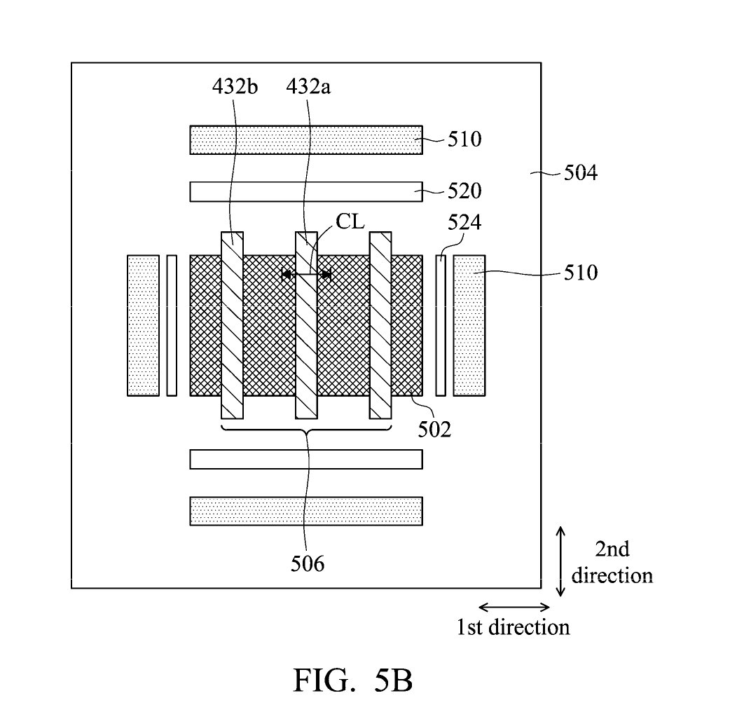

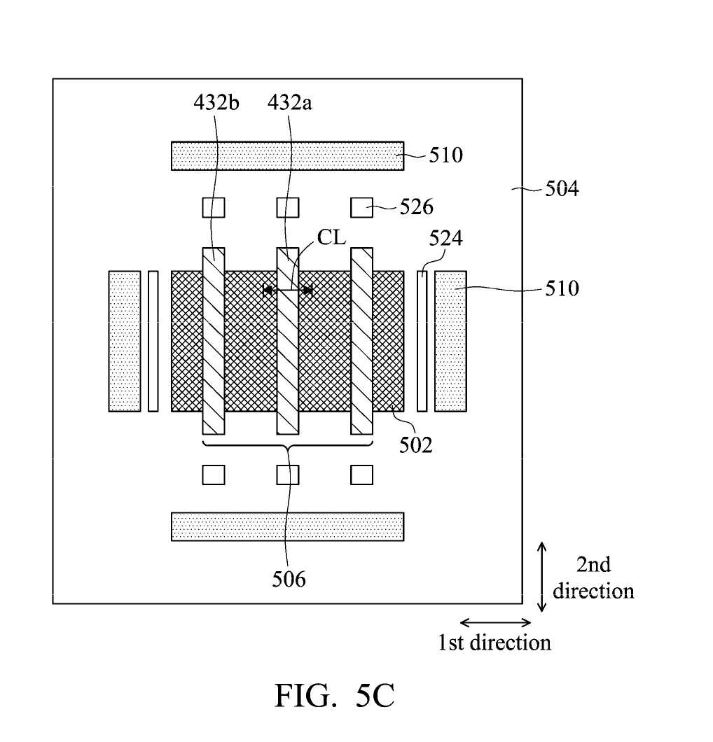

Referring to FIGS. 5A to 5C, illustrated are top plan views of embodiments of a semiconductor integrated circuit device having dummy patterns formed at the two ends of the PMOS transistor in a direction of the device width (perpendicular to the channel length) of the PMOS transistors between the dummy diffusion areas and the diffusion area.

Referring to FIG. 5A, the active region 502 having a diffusion area 502 may be surrounded and defined by the isolation region 504. An array of CMOS transistors 506 fabricated by the gate last process described in FIGS. 4A-4E is formed over the diffusion area 502. Referring to FIG. 5A, the array of the CMOS transistors 506 may at least comprise a PMOS transistor 432a adjacent to an NMOS 432b transistor. Each of the PMOS transistor 432a and the NMOS transistor 432b may have metal gate, high-k dielectric, and source/drain regions sandwiching the metal gate in a first direction. In other words, each of the PMOS transistor 432a and the NMOS transistor 432b may have a metal gate electrode and a channel length in a first direction. It should be noted that although only one PMOS transistor and one NMOS transistor are shown in FIG. 5A, other active features such as, logic circuits, resistors, inductors (nFET), capacitors, p-channel field effect transistors (pFET), n-channel field effect transistors or bipolar junction transistors (BJT) or other PMOS and NMOS transistors, can be also formed over the active region 502. Dummy diffusion areas 510 may be formed over the isolation region 504. In this embodiment, the PMOS transistor 432a may have a device length L along a first direction parallel with the channel length CL of the PMOS transistor 432a and have a device width W along a second direction perpendicular to the channel length CL of the PMOS transistor 432a. In an embodiment, the device width W of the PMOS transistor 432a may be greater than about 0.9 μm and/or greater than the device length L of the PMOS transistor 432a. In some embodiments, the NMOS transistor 432b and/or other active features may be arranged with the PMOS transistor 432a in a row along the first direction and have similar or same device length and width with those of the PMOS transistor 432a.

The dummy diffusion areas 510 may be formed over the isolation area 504 with surrounding and spacing apart from the diffusion area 502. In an embodiment, dummy polygate structures corresponding to the CMOS transistors 506 in the diffusion area 502 may be formed over the dummy diffusion areas 510.

In addition, dummy patterns 520 may be formed at the two ends of the CMOS transistors (including PMOS transistor 432a and the NMOS transistor 432b) in a direction of the device width W of the PMOS transistors. The dummy patterns 520 may be a sacrificial layer that may prevent or reduce erosion portions from forming on the metal gate electrodes 430a and 430b of the transistors 432a and 432b near the center of the array of CMOS transistors 506. In an embodiment, the dummy patterns 520 may comprise polysilicon or metal. The dummy patterns 520 may have a top leveled with a top of the CMOS transistors 506. The dummy patterns 520 may be extended and have a length which is substantially equal to the length of the diffusion area 502 and/or the length of the dummy diffusion area 510 along the first direction. In an embodiment, the dummy patterns 520 may be formed simultaneously with the dummy diffusion areas 510. Thus, no extra photomasks are needed for forming the dummy patterns 420. In another embodiment, the dummy patterns 520 may be formed at any intermediate stages before the CMP processes 440 and 442 performed to the PMOS and NMOS transistors 432a and 432b. The dummy patterns 520 at the two ends of the CMOS transistors 506 may be symmetric to each other corresponding to the diffusion area 502 in the top plan view.

According to another embodiment of the present invention, as shown in FIG. 5B, the integrated circuit device may further comprise dummy patterns 524 formed over the isolation regions 502 and at the two sides of the diffusion area 502 in the first direction. In this embodiment, the same reference number represents the same or similar device shown in preceding embodiments. In addition to dummy patterns 520 which are formed at the two sides of the CMOS transistors 506 in the second direction perpendicular to the channel length CL, the dummy patterns 522 may be also formed at the two sides of the diffusion area 502 and between the dummy diffusion areas 510 and the diffusion area 502 in the first direction parallel with the channel length CL. As such, the dummy patterns 520 and 522 may provide a symmetry pattern around the diffusion area, and therefore may further prevent or reduce the over-polishing and/or dishing effect during several CMP processes in the gate last process. The dummy patterns 522 may comprise same or similar materials as the dummy patterns 520. Alternatively, the dummy patterns 520 and 522 may comprise different materials having different etch selectivities. The dummy patterns 522 may have a top leveled with a top of the CMOS transistors 506.

According to further other embodiments of the present invention, as shown in FIG. 5C, the dummy patterns 526 at the two sides of the CMOS transistors 506 in the second direction may be a plurality of separated blocks arranged in a row along the first direction. In this embodiment, the same reference number represents the same or similar device shown in preceding embodiments. Referring to FIG. 5C, in an embodiment, each of the separated dummy patterns 526 may be corresponded to one of the PMOS or NMOS transistor and have substantially the same length with to the device length L of its corresponded PMOS and NMOS transistor 432a or 432b in the first direction. Thus, the dummy patterns may be formed simultaneously with the PMOS and NMOS transistors 432a and 432b without using additional photomasks. In some embodiments, the dummy patterns 526 at the two ends of the CMOS transistors 506 may be symmetric to each other corresponding to the diffusion area 502 in the top view.

The dummy patterns 520 and 522 may have a sacrificial function so that erosion portions at the center portion of the metal gate electrode 430a of the PMOS transistor 432a are not formed during the CMP process 442 performed to the NMOS transistor 432b. Thus, the metal gate electrode 430a of the PMOS transistor 432a can have a smooth and flat upper surface even if it is fabricated by a gate last process. The AVt of the PMOS transistor can be significantly improved and can even have a similar performance with that of the PMOS transistor having a polysilicon gate electrode, since there's no erosion defects formed on the metal gate electrode of the PMOS transistor. A precise analog metal gate/high-k CMOS circuit design is applicable.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor integrated circuit device comprising:
a diffusion area defined by an isolation region in a substrate;
a PMOS transistor comprising a metal gate and a high-k dielectric over the diffusion area and source/drain regions sandwiching the metal gate in a first direction;
a plurality of dummy diffusion areas surrounding and spaced apart from the diffusion area; and
a plurality of first dummy patterns at the two sides of the PMOS transistor in a second direction perpendicular to the first direction and between the dummy diffusion areas and the diffusion area.

2. The semiconductor integrated circuit device of claim 1, wherein the PMOS transistor has a device width greater than about 0.9 μm along the second direction.

3. The semiconductor integrated circuit device of claim 1, wherein the PMOS transistor has a device length along the first direction which is smaller than the device width.

4. The semiconductor integrated circuit device of claim 1, wherein the plurality of the first dummy patterns has a top leveled with a top of the PMOS transistor.

5. The semiconductor integrated circuit device of claim 1, further comprising a plurality of second dummy patterns formed at the two sides of the PMOS transistor in the second direction and between the dummy diffusion areas and the diffusion area.

6. The semiconductor integrated circuit device of claim 1, wherein the plurality of first dummy patterns comprises polysilicon or metal.

7. The semiconductor integrated circuit device of claim 1, wherein the plurality of first dummy patterns has a length along the first direction which is substantially equal to a length of the diffusion area along the first direction.

8. The semiconductor integrated circuit device of claim 1, wherein each of the plurality of first dummy patterns has a length along the first direction which is substantially equal to a device length of the PMOS transistor along the first direction.

9. The semiconductor integrated circuit device of claim 1, further comprising a plurality of NMOS transistors over the diffusion area, and wherein the plurality of NMOS transistors and the PMOS transistor are formed by a gate last process.

10. A semiconductor integrated circuit device comprising:
an active region which has a diffusion area in a substrate and is defined by an isolation region;
a plurality of PMOS transistors, directly over the diffusion area, having a channel length parallel with a first direction;
a plurality of dummy diffusion areas on the isolation region and surrounding the diffusion area; and
a plurality of dummy patterns over the isolation region and between the dummy diffusion areas and the diffusion area, wherein the plurality of dummy patterns is only formed at the two sides of the plurality of PMOS transistor in a second direction perpendicular to the first direction.

11. The semiconductor integrated circuit device of claim 10, wherein the plurality of POMS transistors has a device width greater than 0.9 μm along the second direction.

12. The semiconductor integrated circuit device of claim 11, wherein the plurality of PMOS transistors has a device length along the first direction which is smaller than the device width.

13. The semiconductor integrated circuit device of claim 10, wherein the plurality of dummy patterns has a top leveled with a top of the PMOS transistors.

14. The semiconductor integrated circuit device of claim 10, wherein the plurality of dummy patterns has a length along the first direction which is substantially equal to a length of the active region along the first direction.

15. The semiconductor integrated circuit device of claim 10, wherein each of the plurality of dummy patterns is corresponded to one of the PMOS transistors and has the same length with its corresponded PMOS transistor along a direction parallel to the first edge of the active region.

16. A semiconductor integrated circuit device comprising:
a diffusion area defined by an isolation region in a substrate
a PMOS transistor comprising a metal gate and a high-k dielectric over the diffusion area and source/drain regions sandwiching the metal gate in a first direction, wherein has a device width greater than 0.9 μm along a second direction perpendicular to the first direction;
a NMOS transistor over the diffusion area and adjacent with the PMOS transistor, wherein the NMOS and the PMOS transistors are formed by a gate last process;
a plurality of diffusion areas surrounding and spaced apart from the active region; and
a plurality of first dummy patterns at the two sides of the PMOS transistor in the second direction and between the dummy diffusion areas and the diffusion area.

17. The semiconductor integrated circuit device of claim 16, wherein the PMOS transistor has a device length along the first direction and smaller than the device width.

18. The semiconductor integrated circuit device of claim 16, wherein the plurality of dummy patterns extends in the first direction with crossing over the PMOS transistor and the NMOS transistor.

19. The semiconductor integrated circuit device of claim 16, wherein each of the plurality of first dummy patterns is corresponded to one of the PMOS or NMOS transistor and has substantially the same length with its corresponded PMOS or NMOS transistor along the first direction.

20. The semiconductor device of claim 16, further comprising a plurality of second dummy patterns formed at the two sides of the PMOS transistor in the second direction and between the dummy diffusion areas and the diffusion area.

21. The semiconductor device of claim 16, wherein the plurality of dummy patterns has a top leveled with a top of the PMOS transistor and the NMOS transistor.
